(19) United States
(12) Patent Application Publication
(10) Pub. No.: US 2011/0059407 A1
(43) Pub. Date: Mar. 10, 2011

(54) DOUBLE PATTERNING STRATEGY FOR FORMING FINE PATTERNS IN PHOTOLITHOGRAPHY

(75) Inventors: Li-Te S. LIN, Hsinchu (TW); Yen-Shuo SU, Jhubei City (TW); Hsueh-Chang SUNG, Zhubei City (TW); Feng-Cheng HSU, Taipei County (TW); Chun Hsiung TSAI, Xinpu Township (TW); Shiang-Bau WANG, Pingzchen City (TW); Chun-Kuang CHEN, Hsinchu (TW)

(73) Assignee: TAIWAN SEMICONDUCTOR MANUFACTURING COMPANY, LTD., Hsinchu (TW)

(21) Appl. No.: 12/871,185

(22) Filed: Aug. 30, 2010

Related U.S. Application Data
(60) Provisional application No. 61/240,798, filed on Sep. 9, 2009.

(51) Int. Cl. G03F 7/20

(52) U.S. Cl. 430/326; 430/325

(57) ABSTRACT

A method of lithography patterning includes forming a first resist pattern over a substrate, baking the first resist features, hardening the first resist features, forming a second resist layer within the hardened first resist features, and patterning the second resist layer to form at least one second resist feature between the hardened first features.

### CROSS REFERENCE

The present application claims priority of U.S. Provisional Patent Application Ser. No. 61/240,798, filed on Sep. 09, 2009, which is incorporated herein by reference in its entirety. The present disclosure is related to the following commonly-assigned U.S. patent applications, the entire disclosures of which are incorporated herein by reference: U.S. application Ser. No. 11/948,444 filed Nov. 30, 2007 by inventors Feng-Cheng Hsu and Chun-Kuang Chen for “DOUBLE PATTERNING STRATEGY FOR CONTACT HOLE AND TRENCH IN PHOTOLITHOGRAPHY” (attorney reference TSMC 2007-0484), and: U.S. application Ser. No. 12/047,086 filed Mar. 12, 2008 by inventors Feng-Cheng Hsu and Chun-Kuang Chen for “DOUBLE PATTERNING STRATEGY FOR CONTACT HOLE AND TRENCH IN PHOTOLITHOGRAPHY” (attorney reference TSMC 2007-0660).

### BACKGROUND

Semiconductor technologies are continually progressing to smaller feature sizes, for example down to feature sizes of 65 nanometers, 45 nanometers, and below. A patterned photoresist (resist) layer used to produce such small feature sizes typically has a high aspect ratio. Maintaining a desired critical dimension (CD) can be very difficult for various reasons, especially for a resist layer with a high aspect ratio. The double patterning processes have been introduced to form various features with smaller dimensions. However, conventional double patterning processes involve multiple etching processes with high manufacturing cost and low throughput.

### BRIEF DESCRIPTION OF THE DRAWINGS

Aspects of the present disclosure are best understood from the following detailed description when read in association with the accompanying figures. It is noted that, in accordance with the standard practice in the industry, various features in the drawings are not drawn to scale. In fact, the dimensions of illustrated features may be arbitrarily increased or decreased for clarity of discussion.

FIGS. 1 through 8 are sectional views of one embodiment of a semiconductor device during various fabrication stages.

FIG. 9 is a flowchart showing one embodiment of a method of lithography patterning.

### DETAILED DESCRIPTION

It is understood that the following disclosure provides many different embodiments, or examples, for implementing different features of various embodiments. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

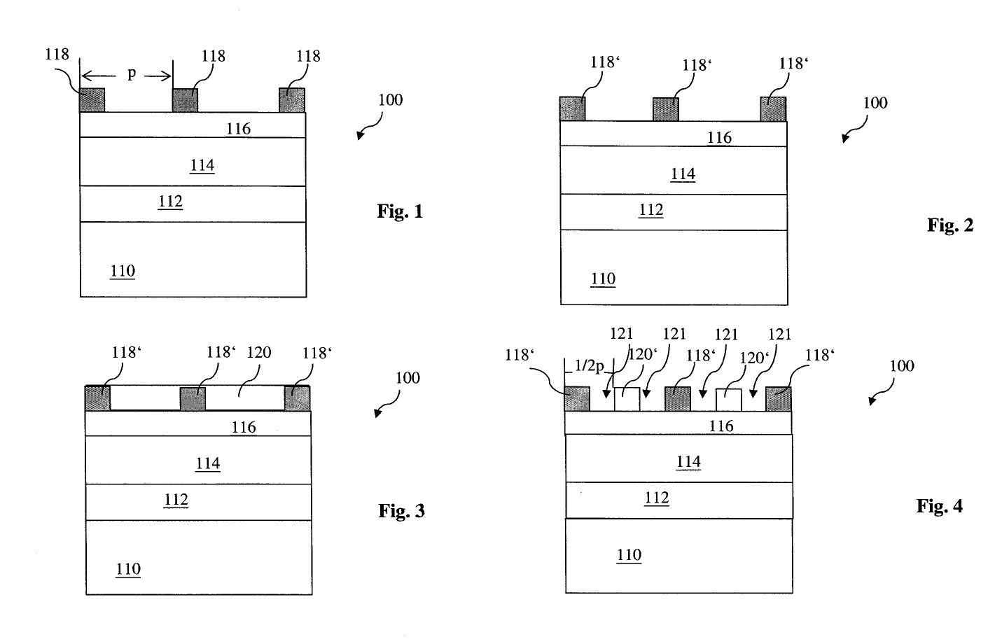

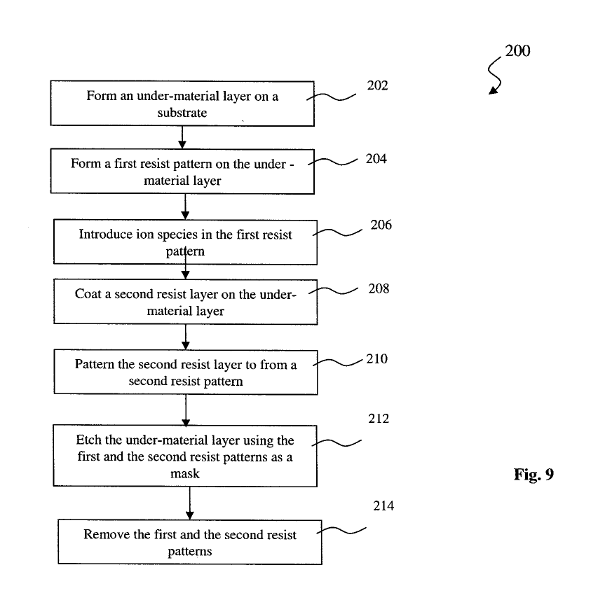

Referring to FIGS. 1 and 9, the method 200 may begin at step 202 by forming one or more underlying material layer (also referred to as an “under-material” layer) on the substrate 110. The substrate 110 may be made of silicon, some other suitable elementary semiconductor, such as diamond or germanium; a suitable compound semiconductor, such as silicon carbide, indium arsenide, or indium phosphide; or a suitable alloy semiconductor, such as silicon germanium carbide, gallium arsenic phosphide, or gallium indium phosphide. Alternatively, the substrate 110 may include a non-semiconductor material such as a glass for thin-film-transistor liquid crystal display (TFT-LCD) devices, or fused quartz or calcium fluoride for a photomask (mask). The substrate 110 may include various doped regions, dielectric features, and multilevel interconnects. In one embodiment, the substrate 110 includes various doped features for various microelectronic components, such as a complementary metal-oxide-semiconductor field-effect transistor (CMOSFET), imaging sensor, memory cell, and/or capacitive element. In another embodiment, the substrate 110 includes conductive material features and dielectric material features configured for coupling and isolating various microelectronic components, respectively. In another embodiment, the substrate 110 includes one or more material layers formed thereon.

The under-material layer may be a single material or layers of different materials. In the embodiment shown in FIGS. 1-9, a material layer 112 is formed on the substrate 110. The material layer 112 may be a dielectric material, such as silicon oxide and/or low dielectric-constant (low-k) material. In other embodiments, the material layer 112 may include silicon, poly-silicon, dielectric material, conductive material or combinations thereof. The material layer 112 may have a thickness ranging between about 100 angstroms and about 9000 angstroms. For example, the material layer 112 may have a thickness ranging between about 1000 angstroms and 3500 angstroms. In one embodiment, the material layer 112 serves as an interlayer dielectric (ILD) or inter-metal dielectric (IMD). The dielectric materials used for ILD or IMD includes silicon oxide and low-k dielectric materials with a dielectric constant less than about 4. Suitable low-k dielectric materials include fluorinated silica glass (FSG), carbon doped silicon oxide, BLACK DIAMOND® (Applied Materials of Santa Clara, Calif.), XEROGEL, AEROGEL, amorphous fluorinated carbon, Parylene, BCB (bis-benzocyclobutenes), SILK (Dow Chemical, Midland, Mich.), polyimide, and/or other proper porous polymeric materials. The dielectric material may be formed by a suitable process including spin-on coating or chemical vapor deposition (CVD).

A mask layer 114 may be additionally formed on the material layer 112. In the present embodiment, the mask layer 114 includes silicon nitride, silicon oxynitride, or other suitable material film formed by a suitable process, such as CVD deposition. The mask layer 114 may have a thickness ranging between about 50 angstroms and about 1000 angstroms. The mask layer 114 can function as a hard mask during a later etching process for patterning the material layer 112 and/or the substrate 110.

Additionally, an anti-reflective coating (ARC) layer 116 may be formed on the mask layer 114 to reduce reflection during lithography exposing processes, also referred to as a top anti-reflective coating (TARC) layer or bottom anti-reflective coating (BARC) layer. In one example, the ARC layer may include organic BARC material formed by a spin-coating technique. The ARC layer 116 may have a thickness ranging from about 50 angstroms to about 2000 angstroms. The ARC layer 116 may be eliminated if the mask layer 114 can function both as a mask layer and an anti-reflective layer. In various embodiments, different combinations of the provided material layers or a subset thereof may be used as the under material layer in various applications.

Still referring to FIGS. 1 and 9, the method 200 proceeds to step 204 by forming a first resist pattern 118 on the ARC layer 116. The first resist pattern 118 , in one embodiment, is a positive tone resist (positive resist) pattern formed by exposing and developing a first positive resist layer. In another embodiment, the first resist pattern 118 is a negative tone resist (negative resist) pattern formed by exposing and developing a first negative resist layer. Preferably, the first resist pattern 118 is a positive resist pattern. The positive resist is characterized as that the exposed regions will be removed by the developing solution. In one embodiment, the positive resist pattern 118 includes chemical amplifier (CA) resist. The CA resist includes photoacid generator (PAG) that can be decomposed to form acid during a lithography exposure process. More acid can be generated as a result of catalytic reaction. As one example of the formation, the first positive resist layer is formed on the semiconductor device 100 and then patterned by a first lithography process to form the positive resist pattern 118 as illustrated in FIG. 1. The first positive resist pattern 118 includes a plurality of positive resist features and a plurality of openings defined by the positive resist features, such that portions of the under material layer within the openings are uncovered. The first lithography process uses a lithography system and a first mask. The openings of the first positive resist pattern 118 are formed according to a predetermined integrated circuit pattern in the first mask. In one embodiment, the positive resist features include a pitch p, defined as a distance from one feature to adjacent feature of the first resist pattern. The pitch p may range between about 50 nm and about 200 nm. As one example, the pitch is about 100 nm. The first resist pattern 118 may have a thickness ranging between about 500 angstroms and 5000 angstroms. In various examples, the first resist pattern 118 may have a thickness ranging between about 500 angstroms and 3000 angstroms, or between about 500 angstroms and 1500 angstroms. The first lithography process used to form the first resist pattern 118 may include resist coating, exposing, post-exposure baking, and developing. The first lithography process may additionally include soft baking, mask aligning, and/or hard baking. For illustration, the exposing process may be carried out by exposing the semiconductor device 100 under a radiation beam through the first mask.

Referring to FIGS. 2 and 9, the method 200 proceeds to step 206 to include a treatment process applied to the first resist pattern 118 before the formation of the second resist layer 120. The treatment process is designed to provide an energy source on the first resist pattern 118 to break the molecular bonds of the first resist pattern 118 and to make the first resist pattern 118 hardened. Before the hardening process, a baking process may be provided on the first resist pattern 118 to remove the residual de-ionized water and/or chemicals from the developing process. The baking process may harden the first resist pattern 118 to a certain extent. However, it would be better to subject the resist pattern 118 in the specific hardening process to prevent it from being deformed by a later lithography process to form the second resist pattern. The energy source of the hardening process, in one embodiment, is provided by an ion implant bombardment. In other embodiments, the energy source could also include plasma, e-beam, ultraviolet (UV), or combinations thereof. The atomic number of the ion species is preferable not more than about 9 such as to prevent shrinkage of critical dimension of the resist pattern 118. The ion species of the ion implant, for example, could be boron, carbon, fluorine, nitrogen, or combinations thereof. The ion implant process is preferably performed at a relatively high energy and low dose to prevent the ions from being further penetrating and/or diffusing into the under-material layer. In one embodiment, the implant is performed at energy not less than about 5 KeV and a dose of not more than about 8E15 atoms/cm². The ion implant tilting angle is preferably not greater than 7 degree. The first resist pattern 118 is transformed to a treated resist pattern 118′ after the treating process, and is insoluble in a subsequent second resist layer 120.

Referring to FIGS. 3 and 9, the method 200 proceeds to step 208 by forming the second resist layer 120 on the device 100. In one embodiment, the second resist layer 120 is a positive resist layer. In another embodiment, the second resist layer 120 is a negative resist layer. Preferably, the second resist layer 120 is with the same tone as the first resist layer. In one example, the second resist layer 120 is formed on the under-material layer overlying the substrate 110 and within the openings defined by the treated resist pattern 118′. The second resist layer 120 is coated on the device 100 such that the top surface of the second resist layer 120 is about or higher than that of the treated resist pattern 118′ and the treated resist pattern 118′ is covered by the second resist layer 120. In one embodiment, the second resist to be coated is tuned with a low surface tension so that the top surface of the second resist layer is formed on the top surface of the treated resist pattern 118′. In another embodiment, the speed of the spin-on coating is tuned to a low level such that the top surface of the treated resist pattern 118′ is covered by the second resist layer 120.

Referring to FIGS. 4 and 9, the method 200 proceeds to step 210 to pattern the second resist layer 120 with a second lithography process. In the second lithography process, the second resist layer 120 is exposed using a second mask with a second predefined pattern and a lithography system. The second lithography process may further include post-exposure baking, developing, and hard baking. A plurality of exposed resist features and unexposed resist features are formed (not shown) in the second resist layer 120 by the second exposing process. The exposed resist features are then removed by a subsequent developing process and forms a plurality of openings 121 and a plurality of second resist features 120′ on the ARC layer 116.

In one example, the second resist features 120′ are periodically configured and may have a pitch ranging between about 40 nm and about 90 nm. In one embodiment, each of the second resist features 120′ is positioned to horizontally enclose one feature of the treated resist pattern 118′.

The second resist features 120′ are configured relative to the treated resist pattern 118′ to from a combined pattern layer so to utilize a double patterning structure. In one example, the baked resist pattern 118′ and the second resist features 120′ are configured to have a split pitch as half of the pitch of the first resist pattern (½ p). The pitch defined by the baked resist pattern 118′/ the second resist features 120′ and the openings 121 is halved, resulting in a reduced minimum features size

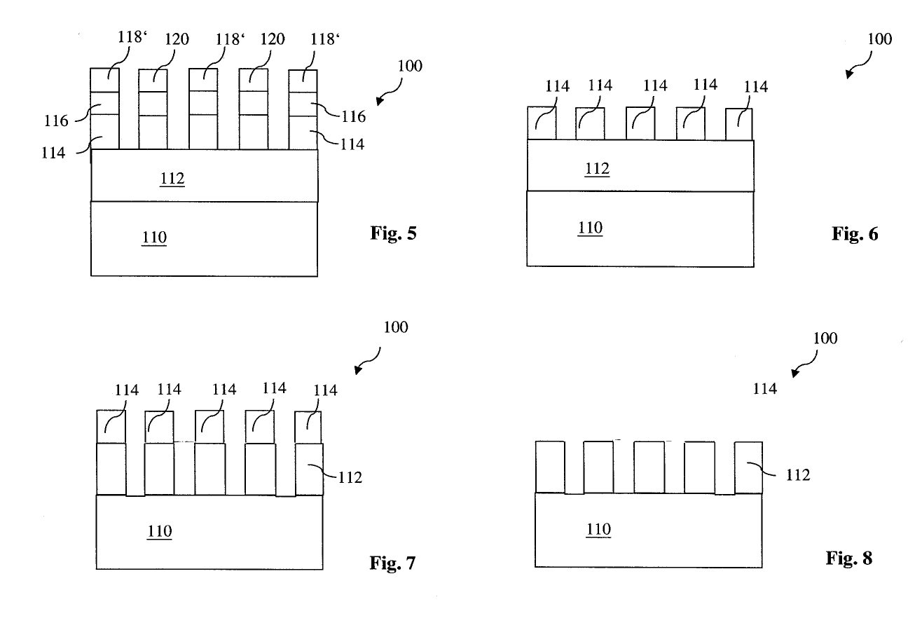

Referring to FIGS. 5 and 9, the method 200 proceeds to step 212 to etch the under-material layer. The ARC layer 116 is partially uncovered by the baked resist pattern 118′ and the second resist features 120′. The uncovered portions of ARC layer 116 are then removed during the subsequent etching process to expose the underlying mask layer 114. The exposed mask layer 114 could be removed during the same etching process as for ARC layer 116 or it could be removed by another separate etching process. The etching process could transfer the pattern of the combined pattern layer into the mask layer 114. The etching process is chosen such that the mask layer 114 has a higher etch rate than that of the material layer 112. Therefore, the mask layer 114 within the openings 121 is substantially removed during the etching process. In one example, the ARC layer 116 within the openings 121 is removed during the etching process at this step.

Referring to FIGS. 6 and 9, the method 200 may proceed to step 214 by removing the baked resist pattern 118′ and the second resist features 120′ after etching the ARC layer 116 within the openings 121. The step 214 may implement a wet stripping or plasma ashing known in the art to remove the baked resist pattern 118′ and the second resist features 120′. For example, an oxygen plasma ashing may be implemented to remove the baked resist pattern 118′ and the second resist features 120′. Additionally, the ARC layer 116 may also be simultaneously removed by the same plasma ashing process. The step of removing the baked resist pattern 118′ and the second resist features 120′ may be alternatively performed after the step of etching the material layer 112.

The material layer 112 can be etched using the patterned mask layer 114 as a hard mask to transfer the defined openings from the mask layer 114 to the material layer 112, as illustrated in FIG. 7 in a sectional view. The material layer 112 is thus patterned to form a plurality of lines, trenches or contact holes. The etching process may be a dry etch, a wet etch, or a combination of wet and dry etches. The mask layer 114 is used as a hard mask at this step and therefore has a higher etching resistance relative to that of the material layer 112. The dry etch may utilize a proper etch gas, such as HBr, Cl₂, SF₆, CF₄, CHF₃, CH₂F₂, CH₄, O₂, Ar, and/or He. The mask layer 114 could be partially consumed during the etching process. The remainder of the mask layer 114 is thereafter removed in the subsequent process, as illustrated in FIG. 8.

The method described above with reference to FIGS. 1 to 9 provides a double patterning process constructed according to various aspects of the present disclosure. This method achieves double exposures and a single etching process to the underlying material layer or the substrate, therefore reducing the manufacturing cost for pitch halving with minimizing CD variation. Other advantages may further present in different embodiments and/or applications. As one example, the dimensional changes of the IC features (such as contact holes or metal lines) associated with the overlay error of the existing double patterning process are eliminated. In another example, since only one etching process is used to etch the under material layer, the manufacturing cost is reduced. The manufacturing throughput and product quality are enhanced, compared with the conventional double patterning and double etching method. In another example, the method 200 is capable of etching a thicker film since the mask layer 114 can be properly chosen with a higher etch resistance.

Various embodiments of a lithography patterning method 200 have been introduced and described. Other modifications, variations, additions, and extensions may be used without departing from the scope of the disclosure. In one example, a plurality of poly-silicon lines are defined by the first positive and second positive resist patterns are formed in the material layer 112. Alternatively, a plurality of trenches may be defined by the first positive and second positive resist patterns are formed in the material layer 112. In another example, the BARC layer and/or mask layer may be eliminated. In another example, the positive and negative resist patterns are directly formed on the substrate 110.

The radiation beam used to expose the first and the second resist layers may be ultraviolet (UV) or EUV, such as a 248 nm beam from a Krypton Fluoride (KrF) excimer laser, or a 193 nm beam from an Argon Fluoride (ArF) excimer laser. The lithography process may utilize other exposing modes or technologies, such as on-axis, off-axis, quadripole, or dipole exposure technologies. The optical exposing process may alternatively be implemented or replaced by other proper methods such as maskless lithography, electron-beam writing, ion-beam writing, and molecular imprint techniques. In another example, the first and second masks used in the method 200 may utilize other mask technologies. For example, the first pattern (or second mask pattern) may be formed in a phase shift mask (PSM). The phase shift mask can print better images than a binary mask.

In one embodiment, the positive resist pattern includes chemical amplifier (CA) resist. In another embodiment, the negative resist layer includes negative resist inert to acid. In furtherance of the embodiment, the negative resist layer includes cyclized synthetic rubber resin, bis-acrylazide, and aromatic solvent. In another embodiment, the positive resist may alternatively include novolac resin, diazonaphthoquinone (DNQ) as photoacitve compound (PAC), and PGME (or PGMEA or ethyl lactate) as solvent. In another example, the negative resist includes silicon-containing material such that the negative resist has an etching resistance greater than that of the positive resist.

As noted earlier in one embodiment, the removing process of the first resist pattern at step 214 may be combined with the step 212. For example, the developing solution used to develop the second resist layer can be tuned or designed to simultaneously remove the first positive resist pattern.

Thus the present disclosure provides a method of lithography patterning. The method includes forming a first resist pattern over a substrate, wherein the first resist pattern includes a plurality of first resist features, baking the first resist features, hardening the first resist features, forming a second resist layer within the hardened first resist features, and patterning the second resist layer to form at least one second resist feature between the hardened first features.

In the disclosed method, the first resist pattern may include a positive tone resist material and the second resist pattern comprises a positive tone resist material. The second positive resist material may be the same as the first positive resist material, or different from the first positive resist material. The first resist pattern may include an etch rate higher than that of the second resist pattern in an etching process. The removing of the first resist pattern may include applying an etching process to selectively remove the first resist pattern relative to the second resist pattern. The removing of the first resist pattern may include applying a solvent to dissolve the first resist pattern. The removing of the first resist pattern may include applying a solvent in which the first resist pattern is soluble and the second resist pattern is insoluble in that solvent. The method may further include etching the substrate within various openings of the second resist pattern after the removing of the first resist pattern. The etching of the substrate may include etching the substrate to form a plurality of contact holes in the substrate. The etching of the substrate may include etching the substrate to form a plurality of trenches in the substrate.

The present disclosure also provides another embodiment of a method of double patterning. The method includes forming a first positive resist pattern on a substrate, the first positive resist pattern is formed by a first positive resist layer having a plurality of openings therein, and the first positive resist layer comprises thermal-acid generator, cross-linker, or high-dissolution agent; baking the first positive resist pattern to form a baked resist pattern; forming a second positive resist layer on the substrate and within the plurality of openings of the baked resist pattern; exposing the second positive resist layer to form a plurality of exposed resist features and a plurality of unexposed resist features on the substrate; and forming a second resist pattern by providing a developer solvent to remove the baked resist pattern and the exposed features, leaving the unexposed features.

In various embodiments, the substrate includes a semiconductor material layer. The substrate may further include a dielectric material layer formed on the semiconductor material layer. The method may further include etching the substrate through the plurality of openings defined by the negative resist pattern.

The foregoing has outlined features of several embodiments so that those skilled in the art may better understand the detailed description that follows. Those skilled in the art should appreciate that they may readily use the present disclosure as a basis for designing or modifying other processes and structures for carrying out the same purposes and/or achieving the same advantages of the embodiments disclosed herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a first resist pattern in a first resist layer over a substrate, wherein the first resist pattern includes a plurality of first resist features;
baking the first resist features;
hardening the first resist features;
forming a second resist layer within the hardened first resist features; and
patterning the second resist layer to form at least one second resist feature between the hardened first resist features.

2. The method of claim 1, wherein the first resist layer and the second resist layer are formed from photoresist with same tone.

3. The method of claim 1, wherein the step of hardening includes the step of subjecting the first resist features to an energy source to break molecular bonds within the first resist features.

4. The method of claim 3, wherein the energy source is provided by at least one of ion implantation, plasma treatment, UV treatment, or e-beam treatment.

5. The method of claim 4, wherein the ion species of ion implantation is at least one of boron, carbon, fluorine, nitrogen, or combinations thereof.

6. The method of claim 4, wherein the ion species of ion implantation has an atomic number not exceeding about 9.

7. The method of claim 4, wherein the ion implantation is performed at energy not less than about 5 KeV.

8. The method of claim 4, wherein the ion implantation is performed with a dose not exceeding about 5E15 atoms/cm².

9. A method comprising:
forming a first resist layer over a substrate;
exposing a portion of the first resist layer to radiation in accordance with a first pattern to form a first resist feature;
treating the first resist feature with an energy source;
forming a second resist layer over the substrate; and
patterning the second resist layer in accordance with a second pattern to form a plurality of second resist features distinct from the first resist feature, the first and second resist features forming a combined pattern layer, wherein the first resist feature is interposed between two of the plurality of second resist features.

10. The method of claim 9, wherein the first resist layer is formed by a first positive resist layer having thermal-acid generator, cross-linker, or high-dissolution agent therein.

11. The method of claim 9, wherein the treated first resist feature is insoluble in the second resist layer.

12. The method of claim 9, wherein the energy source is provided by ion implantation.

13. The method of claim 12, wherein the ion species of ion implantation is at least one of boron, carbon, fluorine, nitrogen, or combinations thereof.

14. The method of claim 12, wherein the ion species of ion implantation has an atomic number not exceeding about 9.

15. The method of claim 12, wherein the ion implantation is performed at energy not less than about 5 KeV.

16. The method of claim 12, wherein the ion implantation is performed with a dose not exceeding about 8E15 atoms/cm².

17. The method of claim 12, wherein the ion implantation is performed with a tile angle not exceeding 7 degrees.

18. A method of double patterning, comprising:
forming a first positive resist pattern on a substrate, the first positive resist pattern is formed by a first positive resist layer having a plurality of first lines therein;
introducing ion species in the first lines;
forming a second positive resist layer within the first lines;
patterning the second positive resist layer to form a plurality of second lines; and wherein
at least one of the second lines is interposed between two of the plurality of first lines such that the first lines and the second lines form a combined pattern layer.

19. The method of claim 18, wherein the ion species is at least one of boron, carbon, fluorine, nitrogen, or combinations thereof.

20. The method of claim 18, wherein the ion species is introduced by ion implantation is performed at energy not less about than 5 KeV.

21. The method of claim 18, wherein the ion species has an atomic number not exceeding about 9.
